(19) United States
(12) Patent Application Publication
(10) Pub. No.: US 2023/0221152 A1
(43) Pub. Date: Jul. 13, 2023

(54) METHOD FOR CALIBRATING A VEHICLE STEERING WHEEL MEASURING DEVICE

(71) Applicant: Autoliv Development AB, Vargarda (SE)

(72) Inventors: Sabine FLECHELLE, Colombes (FR); Pierre SABOURIN, Chapet (FR); Basile REBILLAT, Cergyfr (FR)

(21) Appl. No.: 18/000,474

(22) PCT Filed: May 31, 2021
(86) PCT No.: PCT/EP2021/064475

§ 371 Date: Dec. 1, 2022

(30) Foreign Application Priority Data
Jun. 4, 2020 (FR) FR2005875

(51) Int. Cl. G01D 18/00; G01D 5/24; B62D 15/02

(52) U.S. Cl. CPC G01D 18/00; G01D 5/24; B62D 15/02

(57) ABSTRACT

A method for calibrating a measuring device for a vehicle steering wheel, the measuring device comprising a detection sensor, and an acquisition unit, the calibrating method comprising the steps of: placing the vehicle steering wheel with the on-board detection sensor in a reference environment, carrying out a reference measurement, recording the level of the reference signal and/or adjusting and recording at least one initial threshold to be used by the electronic control unit to initiate a driver assistance action, depending on the level of the measured reference signal and/or recording a difference between the level of the reference signal and the initial threshold.

The present invention relates in general to a vehicle steering wheel installed on a motor vehicle, and in particular to a vehicle steering wheel with detection sensors and a measuring device.

Document US2015344060A1 discloses a vehicle steering wheel equipped with sensors for detecting a target's contact with or proximity to the vehicle steering wheel, which are installed on the vehicle steering wheel. However, this document does not provide a solution for guaranteeing reliable measurement of a target's contact with or proximity to the vehicle steering wheel, even when the signal transmitted by one of the sensors is of low strength (contact with or proximity to an occupant's single finger of small size, for example), while taking into account variations during the manufacture of the vehicle steering wheel, of the sensors, of the measurement lines and of the acquisition units. Specifically, variations during manufacture require tolerances and minimum values for the detection thresholds to be provided, which may compromise the detection of a small target.

Document FR3060505(A1) discloses a vehicle steering wheel equipped with sensors for detecting contact and proposes carrying out an in-vehicle or in-factory contact measurement with a so-called “average” hand in contact with the steering wheel. No solution is given for improving the detection of a small target.

Document US20150330931(A1) discloses a vehicle steering wheel equipped with sensors for detecting contact and proposes carrying out an in-vehicle hand-to-vehicle contact measurement when starting, and taking a hand grip value detected previously and recorded if no hand is detected in contact with the steering wheel. No solution is given for improving the detection of a small target.

One object of the present invention is to address the shortcomings of the aforementioned prior art and in particular, firstly, to provide a calibrating method and a manufacturing method for a mass-produced vehicle steering wheel equipped with sensors for detecting a target's contact with or proximity to the vehicle steering wheel in order to guarantee a reliable measurement, even when the target is small in size.

To achieve this, a first aspect of the invention is a method for calibrating a measuring device for a vehicle steering wheel, the measuring device comprising:

a sensor for detecting a target's contact with or proximity to the vehicle steering wheel, installed on the vehicle steering wheel, and

an acquisition unit of an electronic control unit, connected to the detection sensor in order to receive a detection signal, the calibrating method comprising the steps of:

placing the vehicle steering wheel with the on-board detection sensor in a reference environment,

carrying out a reference measurement, in order to measure a reference signal level received by the acquisition unit,

performing at least one of the operations of:

recording the level of the reference signal and/or

adjusting and recording at least one initial threshold to be used by the electronic control unit to initiate a driving assistance action, depending on the level of the measured reference signal and/or

recording a difference between the level of the reference signal and the initial threshold.

The method according to the above implementation provides a step of placing the vehicle steering wheel in a reference environment, in order to then carry out a reference measurement. In other words, the vehicle steering wheel, the sensor and the measurement chain are placed in a known environment, in which the detection sensor should provide a known detection signal level. Consequently, this reference measurement makes it possible to take into account variations during manufacture and acts as a base measurement (“reset”) for the subsequent processing of measurements in normal life, or to adjust the thresholds which act to trigger an action, or to recalibrate these thresholds, to then allow thresholds of low value to be applied. In other words, the members (vehicle steering wheel, sensor(s), acquisition unit, measurement line between the sensor(s) and acquisition unit, etc.) are paired and the reference measurement makes it possible to guarantee measurements in normal life that are not affected by variations in manufacture (thicknesses of components, intrinsic characteristics of materials, etc.). “Reference environment” is understood to be a space in which the vehicle steering wheel may be positioned precisely in a controlled or monitored environment whose impact on the measurement will be zero or negligible, or whose impact on the measurement will be known and repeatable; it may, for example, take the form of a receiving support which may, for example, take the form of a steering column. It is conceivable for the reference environment to occupy a volume of 1 m×1 m×1 m and to comprise only a receiving support. In any case, the reference environment is easily reproduced from one factory to another, in order to guarantee reproducibility of the measurements. Advantageously, the reference environment is free of elements or targets that may be normally detected by the sensors.

According to one implementation, said reference environment may be arranged so as to be free of elements or targets that may be normally detected by the detection sensor. In other words, the sensors of the steering wheel that is placed in the reference environment do not measure any contact with or proximity to a target, such that the output signal has a value of zero or very close to zero, and such a “zero”, or “empty”, measurement makes it possible to recalibrate the empty signal so as then to reliably detect a target of small size. In other words, the measurement in the reference environment, without any target to be detected, makes it possible to quantify the value of the signal (theoretically zero) in such a situation and then to be able to qualify a measurement signal that has a similar but different value as being a measurement of a small target brought about, for example, by the proximity of or contact with a single finger. The measurement in the reference environment (empty or without target) makes it possible to take the level of the reference signal and register it as zero, in order then to be able to guarantee that a small signal variation is actually brought about by a target of small size, even when manufacturing conditions mean that this reference signal exhibits variation from one steering wheel to another.

According to one implementation, the measurement in the reference environment is carried out in the factory, for example under controlled, or at least measured, temperature and/or moisture conditions. Carrying out the measurement in the factory makes it possible to avoid measurement variabilities in the vehicle passenger compartment. Carrying out the measurement under controlled, or at least measured, temperature and/or moisture conditions makes it possible to further improve the reliability of the measurement.

According to one implementation, the recording of the level of the reference signal and/or of the adjusted threshold and/or of the difference is performed in a memory unit of the electronic control unit. In other words, the reference or corrected value, or the difference, is stored locally, in the electronic control unit (also called the ECU) of the vehicle steering wheel measuring device.

According to one implementation, the measuring device may comprise a plurality of sensors for detecting a target's contact with or proximity to the vehicle steering wheel, or

the detection sensor may comprise a plurality of detection regions, and the calibrating method may comprise a reference measurement step for at least one detection sensor individually or for at least one detection region individually, and preferably the calibrating method comprises a reference measurement step for each detection sensor individually or for each detection region individually. Thus, each detection region or sensor is tested individually, for example sequentially.

According to one implementation, the calibrating method may comprise an automatic starting step, initiated by the electronic control unit, in particular after a step of detecting the placement of the vehicle steering wheel in the reference environment. No action is necessary, and the control unit, on detecting placement of the vehicle steering wheel in the reference environment, automatically initiates the calibrating method.

According to one implementation, the calibrating method may comprise a validation step consisting in comparing the reference signal level with at least one predetermined threshold or compliance range. The reference measurement may be used to verify that the level of the reference signal actually fits within an expected signal size.

According to one implementation, the reference environment may be free of any target, such that the reference measurement may be an empty measurement.

According to one implementation, the reference measurement may comprise the steps of:

bringing a predetermined target in proximity to or in contact with the vehicle steering wheel,

measuring the reference signal received by the acquisition unit, with the predetermined target in proximity to or in contact with the vehicle steering wheel. It is possible to add a measurement with a predetermined target in order to also verify the value of the signal in a measurement region far from zero.

According to one implementation, the reference measurement step may be performed by applying a direct or alternating voltage to the sensor. This may typically be a measurement of an electrical capacitance or a variation in capacitance, or a variation in electrical load. The sensor may typically be a capacitive sensor.

According to one implementation, the step of measuring the reference signal level may be performed by measuring a voltage or an electric current.

A second aspect of the invention relates to a method for the mass production of a mass-produced vehicle steering wheel, comprising the calibrating method according to the first aspect of the invention, for example before a phase of dispatching the vehicle steering wheel to be installed on a new vehicle. In other words, the calibrating method is applied to serial and mass production, where all of the vehicle steering wheels are calibrated, in order to overcome variations in mass production.

A third aspect of the invention relates to a method for the mass production of a motor vehicle comprising a mass-produced vehicle steering wheel, comprising the calibrating method according to the first aspect of the invention, for example before a phase of dispatching the new vehicle.

A fourth aspect of the invention relates to a method for assisting in the driving of a vehicle comprising a vehicle steering wheel comprising a measuring device calibrated by means of the calibrating method according to the first aspect of the invention, the driving assistance method comprising a driving assistance step initiated by the electronic control unit based on a comparison between a detection signal from the detection sensor and:

the level of the reference signal, and/or

the adjusted detection threshold, and/or

the difference between the level of the reference signal and the initial threshold.

A fifth aspect of the invention relates to a method for verifying a vehicle steering wheel in the vehicle aftersale phase, the vehicle steering wheel comprising a measuring device calibrated by means of the calibrating method according to the first aspect of the invention, comprising:

a reference measurement verification step, the vehicle steering wheel being placed in a reference environment, and

a step of comparing the reference signal level measured by means of the calibrating method and by means of the verification method. This method, typically carried out during repair or in the aftersale phase, makes it possible to check whether the vehicle steering wheel and its sensors are still operational.

A sixth aspect of the invention relates to a vehicle steering wheel comprising a measuring device with:

at least one sensor for detecting a target's contact with or proximity to the vehicle steering wheel, installed on the vehicle steering wheel, and

an acquisition unit of an electronic control unit, connected to the detection sensor in order to receive a detection signal, the measuring device being specially designed to implement the calibrating method according to the first aspect of the invention.

According to one implementation, the acquisition unit may be an integral part of the electronic control unit.

According to one implementation, the steering wheel may comprise the electronic control unit. Thus, the steering wheel comprises all of the elements for automatically implementing the calibrating method according to the invention.

According to one implementation, the steering wheel may comprise the memory unit in which the level of the reference signal and/or the adjusted threshold and/or the difference is recorded. Thus, the steering wheel contains the reference values for adjusting or processing subsequent measurements, over its lifetime.

A seventh aspect of the invention relates to a motor vehicle comprising a vehicle steering wheel according to the sixth aspect of the invention.

Alternatively, the invention relates to a method for calibrating a measuring device for a vehicle steering wheel, the measuring device comprising:

a sensor for detecting a target's contact with or proximity to the vehicle steering wheel, installed on the vehicle steering wheel and having a detection distance limit beyond which a target is not detected, and

an acquisition unit connected to the detection sensor, forming part of an electronic control unit designed to execute an action if a detection signal from the detection sensor crosses or exceeds at least one target detection threshold, the calibrating method comprising the steps of:

installing the detection sensor on the vehicle steering wheel,

connecting the acquisition unit to the detection sensor,

carrying out a reference detection measurement, the vehicle steering wheel being placed at a distance greater than the detection distance limit from any target detectable by the detection sensor,

measuring a reference detection signal level received by the acquisition unit,

adjusting said at least one target detection threshold, depending on the level of the measured reference detection signal.

Other characteristics and advantages of the present invention will become more apparent upon reading the detailed description of an embodiment of the invention, which is provided by way of example but in no manner limited thereto, and illustrated by the attached drawings, in which:

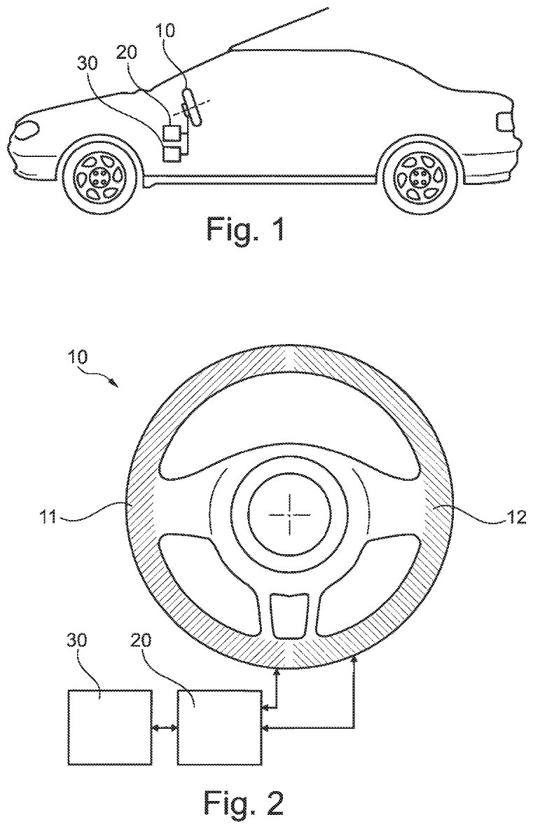

FIG. 1 shows a vehicle equipped with a vehicle steering wheel with a measuring device comprising a sensor for detecting a target's contact with or proximity to the vehicle steering wheel, and an acquisition unit of an electronic control unit;

FIG. 2 shows the vehicle steering wheel and measuring device of the vehicle of FIG. 1 in detail;

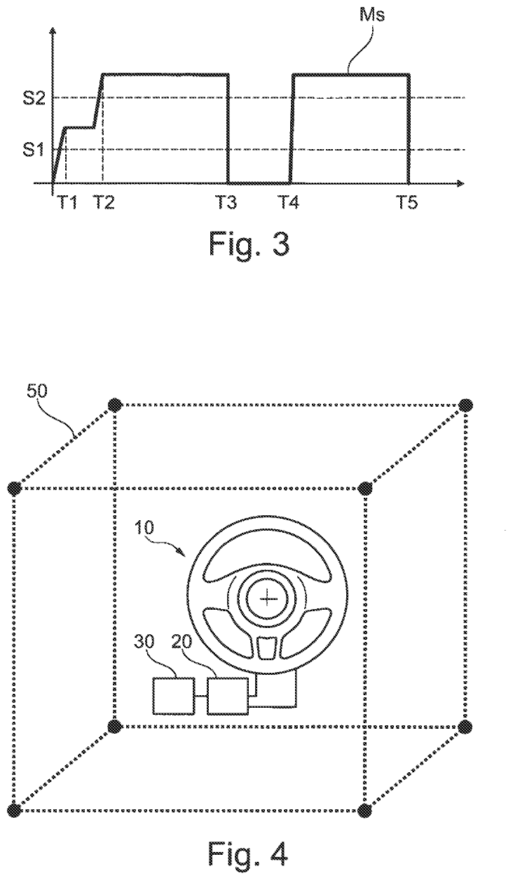

FIG. 3 shows an example of a measurement taken by the measuring device of the vehicle of FIG. 1;

FIG. 4 shows the vehicle steering wheel and measuring device of the vehicle of FIG. 1 which are placed in a reference environment for implementing a calibrating method;

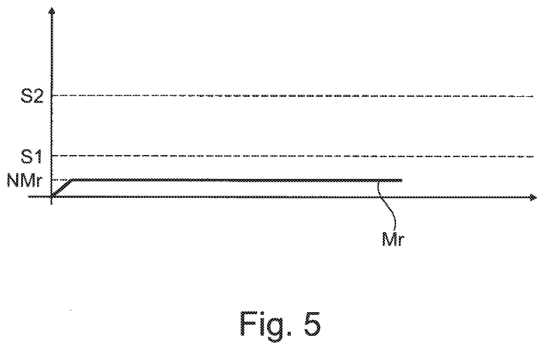

FIG. 5 shows an example of a measurement taken by the measuring device in the situation of FIG. 4.

FIG. 1 shows a motor vehicle comprising a vehicle steering wheel 10, equipped with one or more sensors for detecting a target's contact with or a proximity to the vehicle steering wheel 10, and an acquisition unit 20 of an electronic control unit 30.

In FIG. 1, the acquisition unit 20 and the electronic control unit 30 are distinct and separate from the vehicle steering wheel, but typically at least the acquisition unit 20 is installed on the vehicle steering wheel 10, and it is optionally possible to provide an electronic control unit 30 that incorporates the acquisition unit 20, and is then also installed on the vehicle steering wheel 10. In some cases, there may be a plurality of distinct acquisition units 20, and/or a plurality of electronic control units 30.

The acquisition unit 20 is typically arranged to receive a detection signal from the detection sensor of the vehicle steering wheel 10, and to process this detection signal (this may mean amplification, digitization, multiplexing, etc.) in order to send a processed signal or sampled values to the electronic control unit 30. Consequently, the electronic control unit 30 may compare the values processed by the acquisition unit 20 with thresholds, and initiate specific actions.

For example, if the values processed by the acquisition unit 20 are below a certain threshold, it may be inferred that the driver is not able to take control of the vehicle, and the control unit 30 may send an alert. It is also possible to apply thresholds that reflect the proximity of the vehicle steering wheel to one or more fingers in order to refine, for example, the analysis of the control of the vehicle steering wheel 10 and the alert messages to be sent accordingly.

FIG. 2 shows the vehicle steering wheel and the measuring device of the vehicle of FIG. 1 in greater detail, with the vehicle steering wheel 10 which bears two detection sensors 11 and 12 for detecting a target's (a finger or a palm of a driver's hand) contact with or proximity to the vehicle steering wheel 10. In the simplified and schematic example of FIG. 2, the detection sensor 11 is arranged to detect a target's contact with or proximity to a left-hand portion of the vehicle steering wheel 10, and the detection sensor 12 is arranged to detect a target's contact with or proximity to a right-hand portion of the vehicle steering wheel 10. It is possible to provide more sensors, for example to also distinguish between the front and rear of the vehicle steering wheel 10.

The two detection sensors 11 and 12 are typically capacitive sensors. For example, provision may be made for each detection sensor 11 and 12 to comprise a ground electrode, arranged beneath a covering of the vehicle steering wheel, and a detection electrode, arranged facing the ground electrode and between the latter and the covering of the vehicle steering wheel.

The acquisition unit 20 is connected to each of the two detection sensors 11 and 12 by means of measurement lines, in order to apply a direct or alternating voltage and to measure a detection signal in return, which may be a current or a voltage, so as to determine an electric charge or a variation in electric charge on each detection sensor 11 and 12.

The measurement signal is acquired by the acquisition unit over time and FIG. 3 shows an example of a measurement while the vehicle is being driven, for example for detection sensor 11, which measures or detects a target's contact with or proximity to a left-hand portion of the vehicle steering wheel 10.

According to the example shown in FIG. 3, at time T1, the driver is touching the left-hand portion of the vehicle steering wheel with a single finger, since the measured detection signal Ms is at a level located between thresholds S1 and S2. At time T2 or T4, the measured detection signal Ms is at a level situated above threshold S2, the driver having, for example, gripped the vehicle steering wheel 10 with the palm and all of the fingers. At time T3 or T5, the measured detection signal Ms is at a level of zero, which indicates that the driver is no longer touching the left-hand portion of the vehicle steering wheel 10.

Due to the tolerances and variations in the manufacture of the vehicle steering wheel 10 (geometry, thickness of the covering, etc.), of the detection sensors 11 and 12 (detection area, thickness of the dielectric, positioning on the rim of the vehicle steering wheel, presence of folds, etc.), of the measurement lines (wire length, etc.), of the acquisition unit (measurement precision, etc.), measurement errors arise which may compromise a measurement and analyses resulting therefrom, especially if the detection signal is weak (detection of contact with an occupant's single finger of small size).

To this end, the invention provides a calibrating method to be applied to the measuring device with the assembled vehicle steering wheel during a process of manufacturing mass-produced parts (that is to say the parts that are intended to be fitted to mass-produced vehicles which then go on sale).

In detail, and as shown schematically in FIG. 4, provision is made to place the one or more vehicle steering wheels 10, equipped at least with the acquisition unit 20, in a reference environment 50. The electronic control unit 30 is also shown, but its presence is optional.

Typically, the vehicle steering wheel 10 is positioned on a support (forming, for example, the standard end of a steering column) in the reference environment 50, which is free of any uncontrolled element which could be detected by the detection sensors 11 and 12. In other words, the vehicle steering wheel 10 is positioned on a standardized or predetermined support, in an ideally empty space whose dimensions are, for example, 1 m×1 m×1 m.

Provision may be made for this step of placing the vehicle steering wheel 10 in the reference environment 50 to be at the end of the vehicle steering wheel 10 production line. It is also possible to provide this step of placing the vehicle steering wheel 10 in the reference environment 50 in the vehicle production line, at the point where the vehicle steering wheel 10 is added.

Once the vehicle steering wheel 10 and the measuring device (at least the detection sensors 11 and 12 and the acquisition unit 20) have been placed in the reference environment 50, a reference measurement may be initiated, ideally automatically (the support that accommodates the vehicle steering wheel 10 may be equipped with electrical power supply terminals, which allows the acquisition unit 20 and/or the electronic control unit 30, if present, to initiate the reference measurement automatically).

FIG. 5 shows an example of a detection signal received by the acquisition unit 20, with a reference signal level NMr that is slightly higher than zero due to manufacturing variations, while a zero signal was expected.

Consequently, to make the device accurate, provision is made to take this discrepancy into account in future measurements which will be carried out once the vehicle steering wheel 10 is installed in a vehicle.

Provision is then made to record the reference signal level NMr, and/or to adjust and record at least one initial threshold S1 and/or S2, and/or to record a difference between the level of the reference signal NMr and the initial threshold S1 and/or S2. These values are recorded in the acquisition unit 20 and/or the electronic control unit 30, if present, or at the very least in a memory unit attached or specific to the vehicle steering wheel 10, which will also be installed in the same vehicle.

Thus, in future measurements which will be carried out once the vehicle steering wheel 10 is installed in a vehicle, the detection signal may be corrected in order to eliminate the variation specific to the vehicle steering wheel 10 and to its measuring device.

Provision may also be made to discard the vehicle steering wheel 10 if the level of the reference signal NMr is outside a predefined range of values, indicating a manufacturing problem.

In the event of a problem or a check to be carried out once the vehicle has been assembled and/or sold, it is also possible to carry out a verification measurement by disassembling the vehicle steering wheel 10 in order to place it in the reference environment 50 (or a similar reference environment 50) and compare a verification measurement with the level of the reference signal NMr.

According to the example described, the vehicle steering wheel 10 is placed in the reference environment 50 in order to take an “empty” measurement because the reference environment 50 is free of elements that may be detected by the detection sensors 11 and 12. In other words, the sensors 11 and 12 are placed at a distance from any target that is greater than their detection distance, which is defined by a signal that is, for example, less than 5% of full scale, and preferably a signal that is, for example, less than 2% of full scale.

Alternatively, the vehicle steering wheel 10 is placed in the reference environment 50 in order to take a measurement with predetermined targets which are brought into proximity to the vehicle steering wheel 10 in order to generate a signal of a particular level, and a difference is measured between the measurement and the signal of a particular level in order then to recalibrate future measurements, in the same way as above.

It will be understood that various modifications and/or improvements which are obvious for the person skilled in the art may be made to the different embodiments of the invention described in the present description, without departing from the scope of the invention.

1-15. (canceled)

16. A method for calibrating a measuring device for a vehicle steering wheel,
the measuring device comprising:
at least one sensor for detecting a target's contact with or proximity to the vehicle steering wheel, installed on the vehicle steering wheel, and
an acquisition unit of an electronic control unit, connected to the detection sensor in order to receive a detection signal,
the calibrating method comprising the steps of:
placing the vehicle steering wheel with the on-board detection sensor in a reference environment, said reference environment being arranged so as to be free of elements or targets that may be normally detected by the detection sensor,
carrying out a reference measurement, in order to measure a reference signal level received by the acquisition unit,
recording the level of the reference signal and/or
adjusting and recording at least one initial threshold to be used by the electronic control unit to initiate a driving assistance action, depending on the level of the measured reference signal and/or
recording a difference between the level of the reference signal and the initial threshold.

17. The calibrating method according to claim 16, wherein the recording of the level of the reference signal and/or of the adjusted threshold and/or of the difference is performed in a memory unit of the electronic control unit.

18. The calibrating method according to claim 16,
the measuring device comprising a plurality of sensors for detecting a target's contact with or proximity to the vehicle steering wheel, or
the detection sensor comprising a plurality of detection regions,
wherein the calibrating method comprises a reference measurement step for at least one detection sensor individually or for at least one detection region individually, and preferably the calibrating method comprises a reference measurement step for each detection sensor individually or for each detection region individually.

19. The calibrating method according to claim 16, comprising an automatic starting step, initiated by the electronic control unit, in particular after a step of detecting the placement of the vehicle steering wheel in the reference environment.

20. The calibrating method according to claim 16, comprising a validation step consisting in comparing the reference signal level with at least one predetermined threshold or compliance range.

21. The calibrating method according to claim 16, wherein the reference environment is free of any target, such that the reference measurement is an empty measurement.

22. The calibrating method according to claim 16, wherein the reference measurement comprises the additional steps, performed before or after a measurement with the target-free environment, of:
bringing a predetermined target in proximity to or in contact with the vehicle steering wheel,
measuring the reference signal received by the acquisition unit, with the predetermined target in proximity to or in contact with the vehicle steering wheel.

23. The calibrating method according to claim 16, wherein the reference measurement step is performed by applying a direct or alternating voltage to the sensor.

24. The calibrating method according to claim 23, wherein the step of measuring the reference signal level is performed by measuring a voltage or current.

25. A method for the mass production of a mass-produced vehicle steering wheel, comprising the calibrating method according to claim 16, for example before a phase of dispatching the vehicle steering wheel to be installed on a new vehicle.

26. A method for the mass production of a motor vehicle comprising a mass-produced vehicle steering wheel, comprising the calibrating method according to claim 16, for example before a phase of dispatching the new vehicle.

27. A method for assisting in the driving of a vehicle comprising a vehicle steering wheel comprising a measuring device calibrated by means of the calibrating method according to claim 16, the driving assistance method comprising a driving assistance step initiated by the electronic control unit based on a comparison between a detection signal from the detection sensor and:
the level of the reference signal, and/or
the adjusted detection threshold, and/or
the difference between the level of the reference signal and the initial threshold.

28. A method for verifying a vehicle steering wheel in the vehicle aftersale phase, the vehicle steering wheel comprising a measuring device calibrated by means of the calibrating method according to claim 16, comprising:
a reference measurement verification step, the vehicle steering wheel being placed in a reference environment, and
a step of comparing the reference signal level measured by means of the calibrating method and by means of the verification method.

29. A vehicle steering wheel comprising a measuring device with:
at least one sensor for detecting a target's contact with or proximity to the vehicle steering wheel, installed on the vehicle steering wheel, and
an acquisition unit of an electronic control unit, connected to the detection sensor in order to receive a detection signal,
the measuring device being specially designed to implement the calibrating method according to claim 16.

30. A motor vehicle comprising a vehicle steering wheel according to claim 29.
